(19) United States
(12) Patent Application Publication
(10) Pub. No.: US 2016/0041478 A1
(43) Pub. Date: Feb. 11, 2016

(54) Lithography Cluster, Method and Control Unit for Automatic Rework of Exposed Substrates

(71) Applicant: ASML NETHERLANDS B.V., Veldhoven (NL)

(72) Inventor: Johannes Catharinus Hubertus MULKENS, Veldhoven (NL)

(73) Assignee: ASML NETHERLANDS B.V., Veldhoven (NL)

(21) Appl. No.: 14/763,446

(22) PCT Filed: Mar. 18, 2014
(86) PCT No.: PCT/EP2014/055382

§ 371 Date: Jul. 24, 2015

Related U.S. Application Data
(60) Provisional application No. 61/817,851, filed on Apr. 30, 2013.

(51) Int. Cl. G03F 7/20

(52) U.S. Cl. CPC G03F 7/70616

(57) ABSTRACT

A lithography cluster comprises a track unit, a lithography apparatus, a metrology unit, a control unit and a strip unit. The track unit is for applying a layer on a substrate for lithographic exposure. The lithography apparatus is for exposing the layer according to a pattern. The metrology unit is for measuring a property of the exposed pattern in the layer. The control unit is for controlling an automatic substrate flow between the track unit, the lithography apparatus, and the metrology unit. The strip unit is for removing the layer from the substrate. The control unit is constructed and arranged for controlling the automatic substrate flow on the basis of the measured property such that the substrate is directed to the strip unit for removing the layer if a measured property of its pattern falls outside a pre-determined quality range.

### CROSS-REFERENCE TO RELATED APPLICATIONS

This application claims the benefit of U.S. provisional application 61/817,851, which was filed on Apr. 30, 2013 and which is incorporated herein in its entirety by reference.

### FIELD OF THE INVENTION

The present invention relates to a lithography cluster, a method and a control unit for automatic rework of exposed substrates. The lithography apparatus comprises a track unit for applying a layer on a substrate for lithographic exposure, a lithography apparatus for exposing the layer according to a pattern, a metrology unit for measuring a property of the exposed pattern in the layer, a control unit for controlling an automatic substrate flow between the track unit, the lithography apparatus, and the metrology unit.

### BACKGROUND

Such a lithography cluster is known in practice and can be used for applying patterns to a lot (batch) of substrates (for example wafers). In general, a stack of (vertical) patterned layers has to be applied on each substrate of the lot.

According to the known lithography cluster each substrate of the lot might be fed to the track unit for preparing the substrate for exposure. The track unit can provide each substrate with a layer for exposure. Next, the substrate may automatically be fed to the lithographic apparatus for exposing the layer according to a pattern on a mask or reticle. After exposure the substrates may be fed automatically back to the track unit for developing and baking of the exposed layer. Then, a property of the exposed pattern in the layer might be measured and interpreted by an operator using the metrology unit to check whether the pattern meets a quality requirement.

In lithography industry there is a development in time to depict ever smaller features with an increasing degree of accuracy on substrates. Consequently the demands to properties (like substrate flatness) of substrates are increasing. The risk is that if substrates do not fulfill such requirements the pattern generation process may fail.

In practice operators perform a check with the metrology tool of the exposed pattern in the layer of on one or more substrates of the lot and if the result is not satisfactory then at least two types of actions may be performed.

A first type of action is to simply throw the whole lot of substrates away. The idea is that the chance that many substrates of the lot do not meet the (flatness) requirements is likely and that the most efficient approach is to start processing another lot of substrates that does meet the (flatness) requirements.

A second type of action is a manual rework. Each substrate of the lot is measured by the operator with the metrology unit and the information of the measurements is stored. Next, the operator collects the lot and transports the lot to a rework station. For each substrate the applied layer is removed in the rework station. Then, the lot is transported back to the lithography cluster and each substrate is provided with a new layer and exposed by the lithography apparatus, wherein the lithography apparatus is adjusted during exposure on the basis of the stored information.

A disadvantage of the above is that it yields a relative low throughput (number of produced good substrates per hour) of the lithography cluster.

### SUMMARY

Embodiments of the invention aim to provide a lithography cluster, a method and a control unit for automatic rework of exposed substrates yielding a high throughput and a high accuracy. For this, the lithography cluster according to the embodiments of invention is provided with a strip unit for removing the layer from the substrate, wherein the control unit is constructed and arranged for controlling the automatic substrate flow on the basis of the measured property such that the substrate is directed to the strip unit for removing the layer if a measured property of the pattern falls outside a pre-determined quality range. So, if the pattern in the layer does not comply with a pre-determined quality standard, for example caused by exposure of an unflat surface of the substrate (and/or a deformed substrate), the layer may be removed by the strip unit. Next, the substrate may be provided with a new layer in the track unit and subsequently undergo a new exposure by the lithographic apparatus according to the same pattern as used for the exposure of the removed layer.

In an embodiment of the invention, the control unit is constructed and arranged to adjust the settings of the lithographic apparatus on the basis of the measured property for the new exposure. In this way the second exposure may correct, for example, for the specific deformation of the substrate such that the exposed layer will meet the pre-determined quality standard. Since there is no need for an operator to take the substrate out for a manual rework the throughput good substrates of the cluster is increased.

The lithography cluster according to the embodiment of the invention may comprise a lithography apparatus that applies a desired pattern onto a substrate, usually onto a target portion of the substrate. Such a lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Such types of lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

Properties (also called “parameters”) of the patterned substrate that might be measured by the metrology unit are, for example the overlay error between successive layers formed in or on it and critical line width, or the focus position of the pattern. The metrology can be done directly on the device pattern or can be done on specific metrology targets. The metrology unit may make measurements of the microscopic structures formed in lithographic processes by using a technique similar in a scanning electron microscope and various other specialized tools. A fast and non-invasive form of specialized inspection tool is a scatterometer in which a beam of radiation is directed onto a target on the surface of the substrate and properties of the scattered or reflected beam are measured. Providing a scatterometer or other metrology unit separate from the lithographic apparatus allows detailed measurements to be made in parallel with production.

Embodiments of the invention aims to provide a lithography cluster, method and control unit for automatic rework of exposed substrates yielding a high throughput and a high accuracy. Therefore, the lithography apparatus is provided with a strip unit for removing the layer from the substrate, wherein the control unit is constructed and arranged for controlling the automatic substrate flow on the basis of the measured property such that the substrate is directed to the strip unit for removing the layer if a measured property of the pattern falls outside a pre-determined quality range. The strip unit removes the (resist-)layer from the substrate. Preferably, the strip unit is part of a track unit.

According to an embodiment, after removal of the layer, the substrate may be provided with a new (resist-)layer in the track unit and subsequently undergo a new exposure by the lithographic apparatus according to the same pattern as the exposure of the removed layer. The control unit may adjust the settings of the lithographic apparatus on the basis of the measured property for the new exposure.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The patent or application file contains at least one drawing executed in color. Copies of this patent or patent application publication with color drawing(s) will be provided by the Office upon request and payment of the necessary fee.

The accompanying drawings, which are incorporated herein and form part of the specification, illustrate the present invention and, together with the description, further serve to explain the principles of the invention and to enable a person skilled in the relevant art(s) to make and use the invention.

FIG. 1 is a schematic view of a lithography cluster according to the invention;

FIG. 2 is a schematic view of a feedforward control loop of the lithography cluster according to the invention;

FIG. 3 depicts a lithographic apparatus which may be part of a lithography cluster according to the invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals, and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

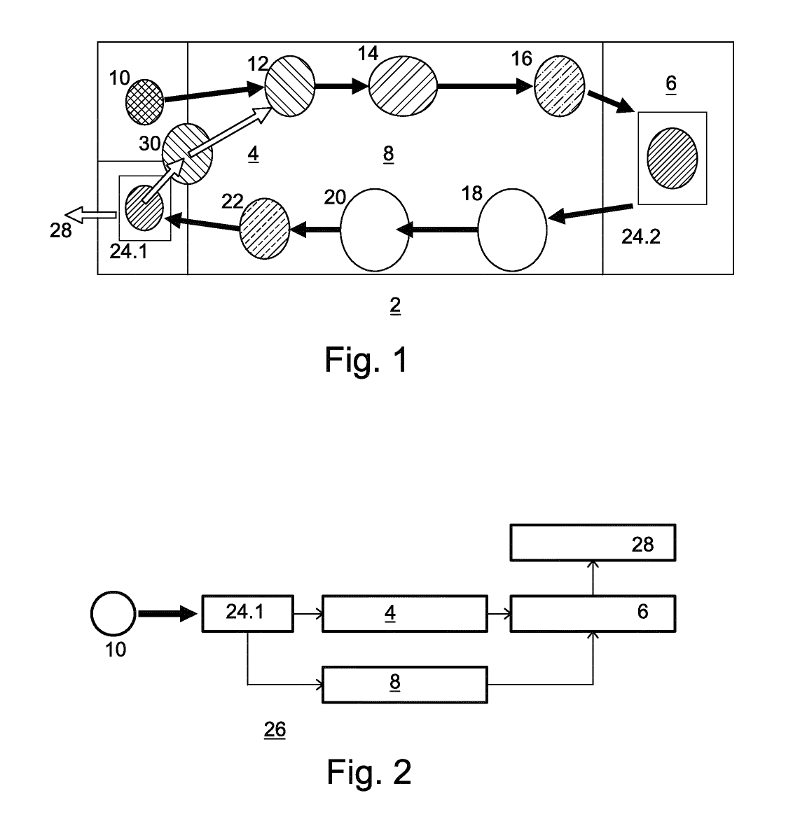

FIG. 1 is a schematic overview of a lithography cluster 2 comprising a track unit 4 and a lithography apparatus 6. The lithography cluster 2 comprises a control unit 8 for controlling an automatic substrate flow between the track unit 4 and the lithography apparatus 6.

In practice a so-called lot of substrates 10 is fed to the lithography cluster 2 for being applied with patterned layers. The track unit 4 comprises a preparation chamber 12 for preparing and cleaning the substrates 10. Next, the substrates 10 enter the spin coater unit 14 which applies a light sensitive layer (thin film) to each substrate. The layer (thin film) is spread evenly over each substrate 10 by rotating the substrate 10 at high speed. Subsequently, a soft bake unit 16 removes the solvents of the applied layer in a soft bake process. Then, the control unit 8 feeds the substrate 10 to the lithography apparatus 6 for exposing the applied layer with a pattern. After that, the exposed substrate 10 is fed by the control unit 8 to the post exposure bake unit 18 for reducing mechanical stress and/or for reducing sensitivity of standing wave phenomena (and also for chemically amplifying the resist and promoting diffusion of carboxylic acid formed during exposure). Subsequently the substrate is fed to the development station 20 for providing a chemical etching process which creates the profile of a patterned layer as exposed by the lithography apparatus (the precise etching process depends on the type of resist). Next, the substrates 10 are baked in hard bake station 22 for hardening the patterned layer. The control unit 8 may (depending on the specific settings of the unit as described later) send the hard baked substrate 10 to a metrology unit 24.1, 24.2 for measuring a property of the pattern in the applied layer. In the example of FIG. 1 the sensor module 24.1 (which is part of metrology unit 24.1, 24.2) performs this function.

The metrology unit 24.1, 24.2 (in this example more in particular sensor module 24.1) can measure information of an exposed layer which has been applied to a substrate 10. An example of the sensor module 24.1 is Yieldstar which is manufactured by ASML. The information relates to a particular property of an exposed pattern in that layer and might be an overlay parameter (an indication of the positioning accuracy of the layer with respect to a previous layer on the substrate or the positioning accuracy of the first layer with respective to marks on the substrate), a focus parameter and/or a critical dimension parameter (line width and its variations) of the depicted image in the layer. Other parameters are image parameters relating to the quality of the depicted image of the exposed pattern.

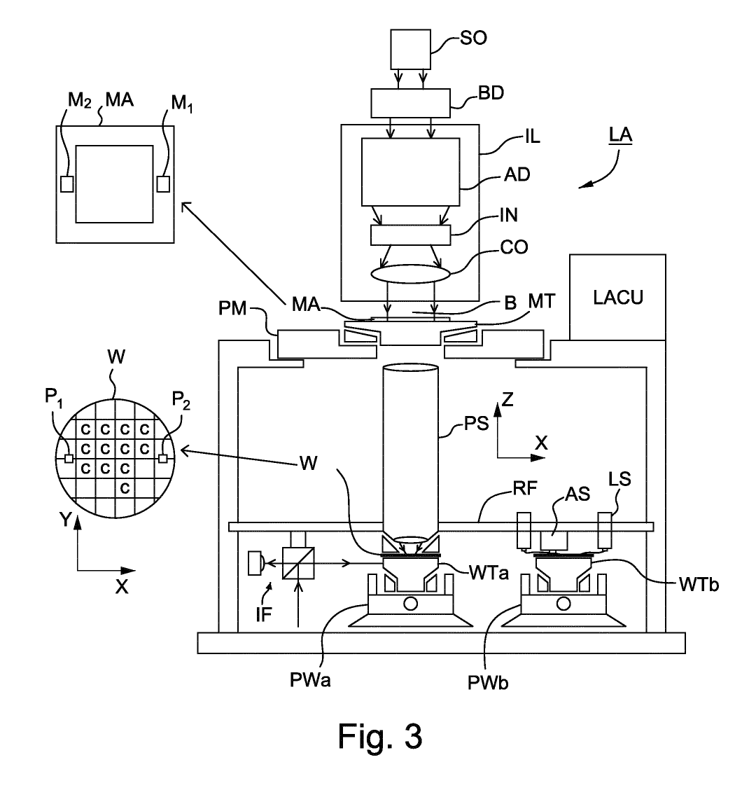

Furthermore, the metrology unit 24.1, 24.2 might be provided with one or more dedicated sensors to measure substrate deformation directly. For example, the metrology unit 24.1, 24.2 may be provided with an alignment sensor (for aligning the substrate on the basis of alignment marks, see the description of FIG. 3) and/or leveling sensor (for measuring the height of the surface of the substrate 10).

The metrology unit 24.1, 24.2 might be completely part of the track unit 4. It is also possible that the sensor module 24.1 is part of the track unit 4 (for example the part for measuring overlay, focus and/or imaging parameters) and that a second part 24.2 is part of the lithography apparatus 6 (comprising the said alignment and/or leveling sensor(s) for measuring substrate deformation). The metrology unit 24.1, 24.2 might also be completely part of the lithography apparatus 6.

FIG. 2 schematically depicts an arrangement of a feedforward control loop 26 of a lithography cluster 2. A substrate 10 is fed to the sensor module 24.1. The sensor module 24.1 measures information of a layer which has been applied to the substrate 10. The information relates to a particular property of an exposed pattern in that layer and might be an overlay parameter (an indication of the positioning accuracy of the layer with respect to a previous layer on the substrate or the positioning accuracy of the first layer with respective to marks on the substrate), a focus parameter and another possible measured property is a critical dimension (line width and its variations) of the depicted image in the layer. Other parameters are image parameters relating to the quality of the depicted image of the exposed pattern.

If the measured property of the applied layer is within a pre-determined quality range the layer is approved. Then the control unit 8 may transport the substrate 10 to a storage unit 28 (for example to a Front Opening Unified Pod (FOUP) or to another storage unit). The substrate 10 may have a next round through the lithography cluster 2 for applying subsequent patterned layers. If the last final layer has been applied to substrate 10, it may be fed (probably via storage unit 28) to an external apparatus for further industrial steps (for example including a slicer for slicing dies out of the substrate 10).

However, if the property of the applied layer measured by the sensor module 24.1 is not within the pre-determined quality range then the control unit 8 may send the substrate 10 to a strip unit 30 for removing the applied (resist-)layer and subsequently to the preparation chamber 12, the spin coater 14 and the soft bake unit 16 for applying a new (resist-)layer on the substrate. This new (resist-)layer is exposed to the same pattern (for example using a reticle having the pattern) as the removed layer by the lithographic apparatus 6. Herewith, the lithographic apparatus 6 is adjusted by the control unit 8 on the basis of measured information by the sensor module 24.1 (and possibly also 24.2). In this way the lithographic apparatus 6 is able to expose the substrate 10 while it corrects for the errors made in the previous exposure of the removed layer. Thus, a correction can be made for (systematic) substrate deformation (unflatness). As shown in FIG. 2 the information measured by the sensor module 24.1 (and possibly also 24.2) is passed to the lithography apparatus in a feedforward way under control of control unit 8.

It is noted that in the case that use is made of a programmable patterning device (instead of a fixed reticle) that the mentioned correction may be made by adjusting the programmable patterning device. In that case the (programmed) pattern of the programmable pattern device is s modified in order to achieve the desired pattern in the exposed layer. In this way the programmable patterning device corrects for errors in the exposed pattern which are caused by substrate unflatness.

Unflatness and/or deformation of substrates 10 causes errors like overlay errors, and imaging errors. This unflatness/deformation is a property of an individual substrate 10 such that the errors have a systematic character. Therefore, these errors can be corrected if in a first phase an exposed layer is measured by the sensor module 24.1 and if in a second phase this layer is removed and a new layer is exposed on the basis of the measurements. It is possible to perform this two stage process for each layer. This will yield substrates which meet high quality standards, but this will also have a throughput (number of good substrates produced per hour) penalty. Hereinafter, this two phase process will be called automatic rework of substrates.

In practice a balance is made between quality of the substrate exposure and the throughput. In practice, the pre-determined quality range may be set on such a level that only a limited amount of (layers) of the substrates 10 have to be stripped and re-exposed. Then, most of the time the measured property will fall inside the pre-determined quality range and the substrate 10 leaves the track unit 4 without entering the strip unit 30 and the other substrates that fall outside the pre-determined quality range will be automatically reworked.

A strategy is to set the pre-determined quality range at a certain level and to reject a complete lot of substrates if too many substrates of the lot appear to have to be automatically reworked. An operator of the lithography cluster 2 can adapt the settings of the control unit 8 in line with this strategy. For example, if it appears that after having processed 10% of the whole lot that 50% or more of the processed substrates have to be automatically reworked then it can be decided to throw away the whole lot of substrates.

A strategy is that the control unit 8 only sends a (for example predetermined) number of substrates of the lot of substrates for a check to the sensor module 24.1 (sensor module 24.1 is in this example situated in the track unit 4) for measuring the applied layer. An option is to perform this selection on a random check basis. An option is that control unit 8 sends substrates 10 to sensor module 24.1 for the said check wherein the substrates 10 are selected on the basis of substrate deformation measurements. For example on the basis of measurements performed by the alignment and/or leveling sensors of the metrology unit 24.2 (which, in this example, is situated in the lithography apparatus 6). An option is that the control unit makes a predetermined selection of substrates in the lot which is send to the sensor module 24.1 (for example substrates at pre-determined intervals). An option is that the control unit 8 dynamically, depending on measurement results of the sensor module 24.1, adapts the selection of substrates that are sent to the sensor module 24.1 (and possibly after that to the strip unit as described above). It is noted that this last option may especially make sense if there is a correlation between the degree of unflatness of the substrates and its position in the sequence in the lot. The mentioned options (and in particular the last mentioned option with the other options) can be combined. An operator of the lithography cluster 2 can adapt the settings of the control unit 8 in line with the strategy and the mentioned options.

It is noted that the strip unit 30 may be part of the track unit 4. The strip unit 30 may be part of the metrology unit 24. Furthermore, the metrology unit 24 may be part of the track unit 4 or the metrology unit 24 may be part of the lithography apparatus 6. Also, as explained hereinbefore, part of the metrology unit 24 may be part of the track unit 4 and another part of the metrology unit 24 may be part of the lithography apparatus 6. The metrology unit 24 and/or the strip unit 30 may be integrated in the housing of the track unit 4.

FIG. 3 schematically depicts a lithographic apparatus (that may be part of the lithography cluster according to the invention) that comprises an illumination system (illuminator) IL configured to condition a radiation beam B (e.g. UV radiation or EUV radiation), a support structure (e.g. a mask table) MT constructed to support a patterning device (e.g. a mask) MA and connected to a first positioner PM configured to accurately position the patterning device in accordance with certain parameters, a substrate table (e.g. a wafer table) WTa or WTb constructed to hold a substrate (e.g. a resist coated wafer) W and connected to a second positioner PWa or PWb configured to accurately position the substrate in accordance with certain parameters, and a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure. The two substrate tables WTa and WTb in the example of FIG. 1 are an illustration of this. The invention disclosed herein can be used in a stand-alone fashion, but in particular it can provide additional functions in the pre-exposure measurement stage of either single- or multi-stage apparatuses.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 3, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as -outer and -inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross section.

The radiation beam B is incident on the patterning device (e.g., mask MA), which is held on the support structure (e.g., mask table MT), and is patterned by the patterning device. Having traversed the mask MA, the radiation beam B passes through the projection system PS, which focuses the beam onto a target portion C of the substrate W. With the aid of the second positioner PWa/PWb and position sensor IF (e.g. an interferometric device, linear encoder or capacitive sensor), the substrate table WTa/WTb can be moved accurately, e.g. so as to position different target portions C in the path of the radiation beam B. Similarly, the first positioner PM and another position sensor (which is not explicitly depicted in FIG. 1) can be used to accurately position the mask MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioner PM.

Similarly, movement of the substrate table WTa/WTb may be realized using a long-stroke module and a short-stroke module, which form part of the second positioner PWa/PWb. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:
1. In step mode, the mask table MT and the substrate table WTa/WTb are kept essentially stationary, while an entire pattern imparted to the radiation beam is projected onto a target portion C at one time (i.e. a single static exposure). The substrate table WTa/WTb is then shifted in the X and/or Y direction so that a different target portion C can be exposed. In step mode, the maximum size of the exposure field limits the size of the target portion C imaged in a single static exposure.
2. In scan mode, the mask table MT and the substrate table WTa/WTb are scanned synchronously while a pattern imparted to the radiation beam is projected onto a target portion C (i.e. a single dynamic exposure). The velocity and direction of the substrate table WTa/WTb relative to the mask table MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.
3. In another mode, the mask table MT is kept essentially stationary holding a programmable patterning device, and the substrate table WTa/WTb is moved or scanned while a pattern imparted to the radiation beam is projected onto a target portion C. In this mode, generally a pulsed radiation source is employed and the programmable patterning device is updated as required after each movement of the substrate table WTa/WTb or in between successive radiation pulses during a scan. This mode of operation can be readily applied to maskless lithography that utilizes programmable patterning device, such as a programmable mirror array of a type as referred to above.

Lithographic apparatus LA is of a so-called dual stage type which has two substrate tables WTa and WTb and two stations—an exposure station and a measurement station—between which the substrate tables can be exchanged. While one substrate on one substrate table is being exposed at the exposure station, another substrate can be loaded onto the other substrate table at the measurement station so that various preparatory steps may be carried out. The preparatory steps may include mapping the surface of the substrate using a level sensor LS and measuring the position of alignment markers on the substrate using an alignment sensor AS. This enables a substantial increase in the throughput of the apparatus. If the position sensor IF is not capable of measuring the position of the substrate table while it is at the measurement station as well as at the exposure station, a second position sensor may be provided to enable the positions of the substrate table to be tracked at both stations.

The apparatus further includes a lithographic apparatus control unit LACU which controls all the movements and measurements of the various actuators and sensors described. LACU also includes signal processing and data processing capacity to implement desired calculations relevant to the operation of the apparatus. In practice, control unit LACU will be realized as a system of many sub-units, each handling the real-time data acquisition, processing and control of a subsystem or component within the apparatus. For example, one processing subsystem may be dedicated to servo control of the substrate positioner PWa/PWb. Separate units may even handle coarse and fine actuators, or different axes. Another unit might be dedicated to the readout of the position sensor IF. Overall control of the apparatus may be controlled by a central processing unit (control unit 8), communicating with these sub-systems processing units, with operators and with other apparatuses involved in the lithographic manufacturing process.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A lithography cluster comprising:
a track unit configured to apply a layer on a substrate for lithographic exposure,
a lithography apparatus configured to expose the layer according to a pattern,
a metrology unit configured to measure a property of the exposed pattern in the layer,
a control unit configured to control an automatic substrate flow between the track unit, the lithography apparatus, and the metrology unit, and
a strip unit configured to remove the layer from the substrate,
wherein the control unit is constructed and arranged for controlling the automatic substrate flow on the basis of the measured property, such that the substrate is directed to the strip unit for removing the layer if a measured property of the pattern falls outside a pre-determined quality range.

2. The lithography cluster according to claim 1, wherein the control unit is constructed and arranged to control the automatic substrate flow such that, if the measured property falls inside the pre-determined quality range, the substrate leaves the track without entering the strip unit.

3. The lithography cluster according to claim 1, wherein the control unit is constructed and arranged for controlling the automatic substrate flow such that each substrate leaving the strip unit is provided with a new layer by the track unit and directed to the lithographic apparatus for a new exposure according to the said pattern, wherein the control unit is constructed and arranged to adjust the settings of the lithographic apparatus for the new exposure on the basis of the measured property.

4. The lithography cluster according to claim 1, wherein the metrology unit comprises a sensor for measuring substrate deformation.

5. The lithography cluster according to claim 1, wherein the control unit is constructed and arranged for controlling the automatic flow such that for a pre-determined subset of substrates of a lot of substrates fed to the lithography cluster measurements by the metrology unit are performed of patterns of exposed layers.

6. The lithography cluster according to claim 1, wherein the control unit is constructed and arranged for controlling the automatic substrate flow such that for a dynamically selected subset of substrates of a lot of substrates fed to the lithography cluster measurements by the metrology unit are performed of patterns of exposed layers, wherein the selection is performed by the control unit on the basis of measurements of the metrology unit.

7. The lithography cluster according to claim 1, wherein the strip unit is part of the track unit.

8. The lithography cluster according to claim 1, wherein the strip unit is part of the metrology unit.

9. (canceled)

10. (canceled)

11. A method for exposing a substrate, comprising the steps:
using a track unit for applying a layer on the substrate for lithographic exposure,
exposing the applied layer according to a pattern by a lithography apparatus,
using a metrology unit for making a measurement of a property of the exposed pattern in the layer,
using a control unit for controlling an automatic substrate flow between the track unit, the lithography apparatus, and the metrology unit,
using a strip unit that is integrated in the track unit for removing the layer if the measured property falls outside a pre-determined quality range.

12. The method according to claim 11 wherein in response to the strip unit removing the layer, the method further comprises:
using the track unit for applying a new layer on the substrate for lithographic exposure,
performing a new exposure of the new layer according to the said pattern with the lithography apparatus,
using the control unit for adjusting the setting of the lithographic apparatus for exposing the new layer on the basis of the measured property.

13. The method according to claim 11, wherein measurements of exposed patterns are performed for a pre-determined subset of substrates of a lot of substrates.

14. The method according to claim 11, wherein measurements of exposed patterns are performed for a dynamically selected subset of substrates of a lot of substrates, wherein the selection is performed by the control unit on the basis of measurements performed by the metrology unit.

15. (canceled)
